(19) United States
(12) Patent Application Publication
(10) Pub. No.: US 2005/0009243 A1
(43) Pub. Date: Jan. 13, 2005

(54) Semiconductor device and method of manufacturing the same, cirucit board, and electronic instrument

(75) Inventor: Jun Taniguchi, Nerima-ku (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/853,288

(22) Filed: May 26, 2004

(30) Foreign Application Priority Data
Jun. 27, 2003 (JP) 2003-184573

(51) Int. Cl. H01L 21/44

(52) U.S. Cl. 438/127

(57) ABSTRACT

A method of manufacturing a semiconductor device including: mounting a semiconductor chip in which an integrated circuit is formed on a wiring board having an interconnecting pattern; mounting a board for electrical connection having a plurality of penetrating conductive sections on the wiring board; disposing a first end surface of each of the penetrating conductive sections to face the interconnecting pattern; electrically connecting the first end surface and the interconnecting pattern; and forming a sealing section which seals the semiconductor chip and the board for electrical connection such that a second end surface of each of the penetrating conductive sections is exposed from the sealing section.

Japanese Patent Application No. 2003-184573, filed on Jun. 27, 2003, is hereby incorporated by reference in its entirety.

### BACKGROUND OF THE INVENTION

The present invention relates to a semiconductor device and a method of manufacturing the semiconductor device, a circuit board, and an electronic instrument.

To achieve space saving, it is known to stack semiconductor devices. To improve the reliability of stackable semiconductor devices, and to raise the manufacturing efficiency thereof, it is preferable that the means of forming this semiconductor device is easy.

### BRIEF SUMMARY OF THE INVENTION

According to a first aspect of the present invention, there is provided a method of manufacturing a semiconductor device comprising:
mounting a semiconductor chip in which an integrated circuit is formed on a wiring board having an interconnecting pattern;
mounting a board for electrical connection having a plurality of penetrating conductive sections on the wiring board, disposing a first end surface of each of the penetrating conductive sections to face the interconnecting pattern and electrically connecting the first end surface and the interconnecting pattern; and
forming a sealing section which seals the semiconductor chip and the board for electrical connection such that a second end surface of each of the penetrating conductive sections is exposed from the sealing section by a transfer molding method.

According to a second aspect of the present invention, there is provided a semiconductor device manufactured by the above method.

According to a third aspect of the present invention, there is provided a semiconductor device comprising:
a wiring board having an interconnecting pattern;
a semiconductor chip mounted on the wiring board and having an integrated circuit;
a board for electrical connection mounted on the wiring board and having an insulating section and a plurality of penetrating conductive sections; and
a sealing section which seals the semiconductor chip and the board for electrical connection;
wherein a first end surface of each of the penetrating conductive sections faces the interconnecting pattern and is electrically connected to the interconnecting pattern;
wherein a second end surface of each of the penetrating conductive sections is exposed from the sealing section; and
wherein the insulating section and the sealing section are formed of different materials.

According to a fourth aspect of the present invention, there is provided a circuit board on which is mounted the above semiconductor device.

According to a fifth aspect of the present invention, there is provided an electronic instrument comprising the above semiconductor device.

### BRIEF DESCRIPTION OF THE SEVERAL VIEWS OF THE DRAWING

FIG. 1 shows a method of manufacturing a semiconductor device according to one embodiment of the present invention.

FIG. 2 shows a method of manufacturing a semiconductor device according to one embodiment of the present invention.

FIG. 3 shows a method of manufacturing a semiconductor device according to one embodiment of the present invention.

FIGS. 4A and 4B show a method of manufacturing a semiconductor device according to one embodiment of the present invention.

FIGS. 5A and 5B show a method of manufacturing a semiconductor device according to one embodiment of the present invention.

FIGS. 6A and 6B show a method of manufacturing a semiconductor device according to one embodiment of the present invention.

FIG. 7 shows a method of manufacturing a semiconductor device according to one embodiment of the present invention.

FIG. 8 shows a method of manufacturing a semiconductor device according to one embodiment of the present invention.

FIG. 9 shows a method of manufacturing a semiconductor device according to one embodiment of the present invention.

FIG. 10 shows a circuit board on which is mounted a semiconductor device according to one embodiment of the present invention.

FIG. 11 shows an electronic instrument having a semiconductor device according to one embodiment of the present invention.

FIG. 12 shows an electronic instrument having a semiconductor device according to one embodiment of the present invention.

### DETAILED DESCRIPTION OF THE EMBODIMENT

The present invention may provide a semiconductor device of high reliability and excellent manufacturing efficiency, and method of manufacture thereof, a circuit board, and an electronic instrument.

(1) According to one embodiment of the present invention, there is provided a method of manufacturing a semiconductor device comprising:
mounting a semiconductor chip in which an integrated circuit is formed on a wiring board having an interconnecting pattern;
mounting a board for electrical connection having a plurality of penetrating conductive sections on the wiring board, disposing a first end surface of each of the penetrating conductive sections to face the interconnecting pattern and electrically connecting the first end surface and the interconnecting pattern; and
forming a sealing section which seals the semiconductor chip and the board for electrical connection such that a second end surface of each of the penetrating conductive sections is exposed from the sealing section by a transfer molding method.

This makes it possible to easily manufacture a semiconductor device in which part of the penetrating conductive sections is exposed from the sealing section. That is to say, this makes it possible to easily manufacture a stackable semiconductor device in which electrical connection with other semiconductor devices can be achieved by means of the penetrating conductive sections.

(2) In this method of manufacturing a semiconductor device, a depression may be formed in the periphery of the second end surface of each of the penetrating conductive sections. Since this makes it possible to prevent the second end surface from being covered by the molding resin in the sealing step, a semiconductor device of high electrical connection reliability can be manufactured.

(3) In this method of manufacturing a semiconductor device, a plurality of protrusions may be formed to surround all of the second end surfaces of the penetrating conductive sections on the edge of a surface of the board for electrical connection opposite to the surface facing the wiring board. Since this makes it possible to prevent the second end surfaces from being covered by the molding resin in the sealing step, a semiconductor device of high electrical connection reliability can be manufactured.

(4) In this method of manufacturing a semiconductor device, a protrusion may be formed to surround the second end surface of each of the penetrating conductive sections on a surface of the board for electrical connection opposite to the surface facing the wiring board. Since this makes it possible to prevent the second end surface from being covered by the molding resin in the sealing step, a semiconductor device of high electrical connection reliability can be manufactured.

(5) A semiconductor device according to one embodiment of the present invention is manufactured by the above-described method.

(6) According to one embodiment of the present invention, there is provided a semiconductor device comprising:
a wiring board having an interconnecting pattern;
a semiconductor chip mounted on the wiring board and having an integrated circuit;
a board for electrical connection mounted on the wiring board and having an insulating section and a plurality of penetrating conductive sections; and
a sealing section which seals the semiconductor chip and the board for electrical connection;
wherein a first end surface of each of the penetrating conductive sections faces the interconnecting pattern and is electrically connected to the interconnecting pattern;
wherein a second end surface of each of the penetrating conductive sections is exposed from the sealing section; and
wherein the insulating section and the sealing section are formed of different materials.

This makes it possible to easily manufacture a semiconductor device in which part of the penetrating conductive sections is exposed from the sealing section. That is to say, this makes it possible to provide a semiconductor device capable of being stacked in multiple layers.

(7) According to one embodiment of the present invention, there is provided a circuit board on which the above semiconductor device is mounted.

(8) An electronic instrument according to one embodiment of the present invention comprises the above semiconductor device.

An embodiment of the present invention is now described with reference to the drawings. The present invention is not, however, limited to the following embodiment.

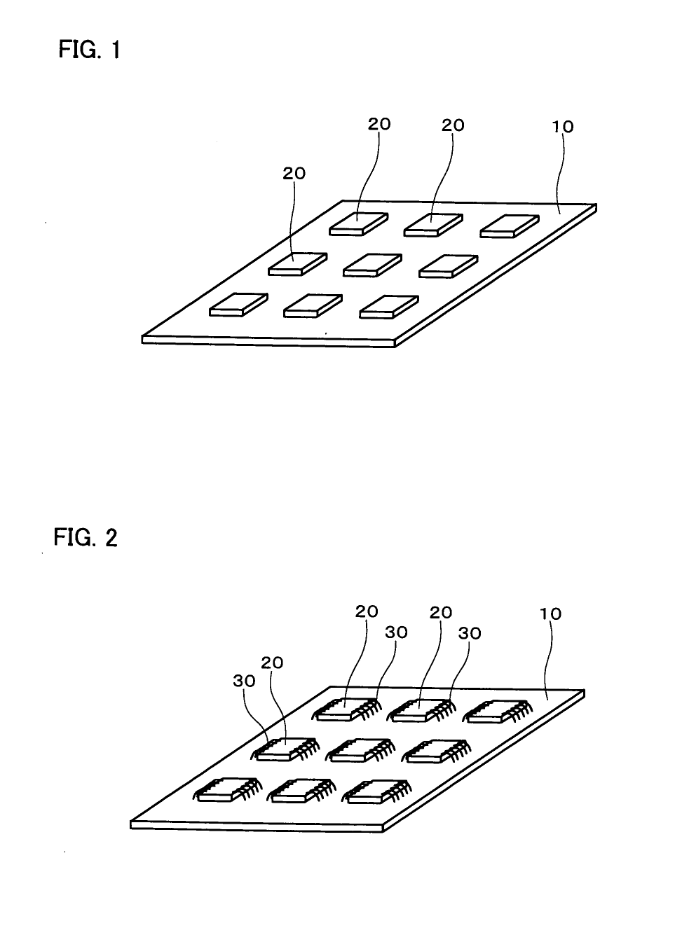

FIGS. 1 to 8 illustrate the method of manufacturing a semiconductor device according to one embodiment of the present invention. As shown in FIG. 1, the method of manufacturing a semiconductor device according to this embodiment includes mounting a semiconductor chip 20 on a wiring board 10.

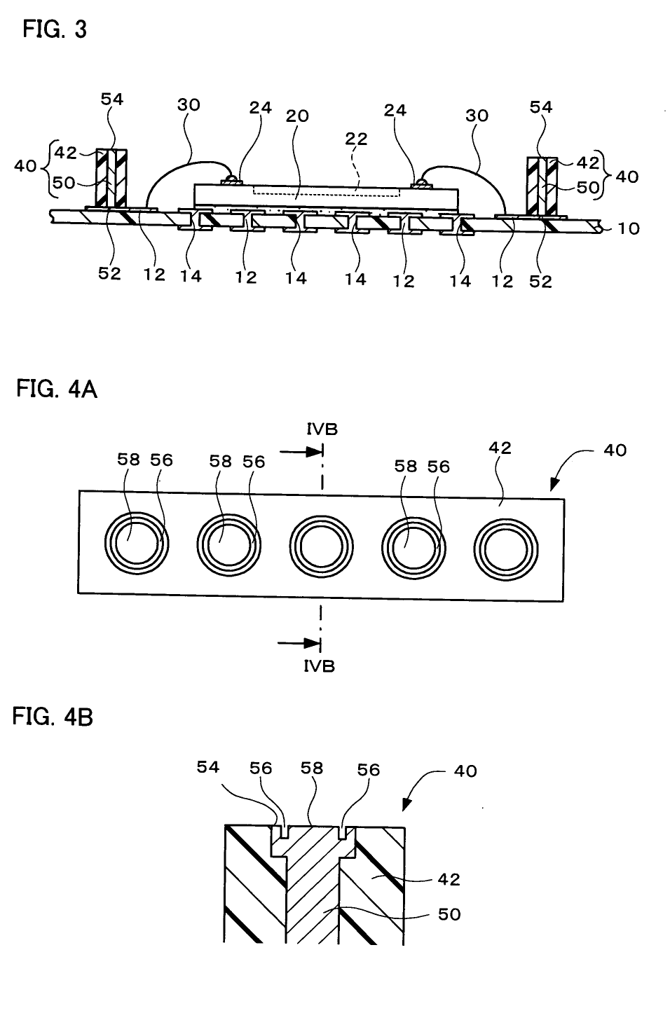

The wiring board 10 may be formed of a material which is either organic (a polyimide board or the like) or inorganic (a ceramic board, glass board or the like), or may be a composite stricture thereof (for example, a glass epoxy board). The plan form of the wiring board 10 is not particularly restricted, but is commonly rectangular. The wiring board 10 may be either a single-layer or multi-layer board. On the wiring board 10 is formed an interconnecting pattern 12 consisting of a plurality of connecting lines. The interconnecting pattern 12 is, however, omitted in FIGS. 1 and 2. In the wiring board 10 is formed a plurality of through holes 14, for electrical connection from one surface to the other (see FIG. 3). The through holes 14 may be filled with an electrically conductive material, or may be formed by through holes formed by plating the inner walls of the hole. By this means, the two surfaces of the wiring board 10 can be electrically connected.

The form of the semiconductor chip 20 is not particularly restricted, but is commonly a rectangular parallelepiped (including a cube). On the semiconductor chip 20 is formed an integrated circuit 22, comprising transistors, memory elements, and the like (see FIG. 3). The semiconductor chip 20 may have a plurality of pads 24 electrically connected to the interior. The pads 24 may be disposed on the edges of the surface of the semiconductor chip 20, along two or four sides of the outline. Alternatively, the pads 24 may be disposed in a central section of the surface of the semiconductor chip 20. The pads 24 may be formed of an aluminum- or copper-based metal. A passivation film (not shown in the drawings) may be formed on the semiconductor chip 20, to avoid at least a part of the pads 24. The passivation film may he formed of, for example, SiO₂, SiN, polyimide resin, or the like. It should be noted that in this method of manufacturing a semiconductor device, the semiconductor chip 20 may be mounted so that the surface opposite to the surface on which the pads 24 are formed opposes the wiring board 10 (see FIG. 3). The semiconductor chip 20 may be fixed to the wiring board 10 by an adhesive. In this case, an insulating adhesive may be used as the adhesive. It should be noted that a plurality of semiconductor chips may be stacked and mounted on the wiring board 10, whereby a semiconductor device having stacked semiconductor chips may be manufactured.

In this embodiment, as shown in FIG. 1, a plurality of semiconductor chips 20 may be mounted on a single wiring board 10, and subsequent processes applied to the plurality of semiconductor chips 20 in a single operation. By this means, since the plurality of semiconductor devices can be formed in a single operation, the production efficiency of the semiconductor device can be raised. However, as an alternative, a single semiconductor chip may be mounted on each wiring board, and the subsequent processes applied to each semiconductor chip.

The method of manufacturing a semiconductor device according to this embodiment may include electrically connecting the semiconductor chip 20 and interconnecting pattern 12. As shown in FIG. 2, the electrical connection of the interconnecting pattern 12 and semiconductor chip 20 may use wires 30. In concrete terms, wires 30 electrically connecting the interconnecting pattern 12 and pads 24 may be formed by a wire bonding process, so as to electrically connect these. The wire bonding process may be any already well-known method, and for example the wires 30 may be formed by the ball bump method. The material of the wires 30 is not particularly restricted, and for example gold wires may be used. It should be noted that the wires 30 may be formed so that the loop height thereof is lower than a board 40 for electrical connection described below.

As shown in FIG. 3, the method of manufacturing a semiconductor device according to this embodiment includes mounting the board 40 for electrical connection having a plurality of penetrating conductive sections 50, on the wiring board 10, and opposing and electrically connecting a first end surface 52 of the penetrating conductive section 50 and the interconnecting pattern 12. As shown in FIG. 3, the electrical connection of the penetrating conductive section 50 and interconnecting pattern 12 may be achieved by contacting the first end surface 52 of the penetrating conductive section 50 and the interconnecting pattern 12. In this case, the board 40 for electrical connection may be fixed to the wiring board 10 by an adhesive (not shown in the drawings). Alternatively, using ACF or ACP, the electrical connection of the two may be achieved by introducing conductive particles between the first surface 52 of the penetrating conductive sections 50 and the interconnecting pattern 12. The board 40 for electrical connection may be disposed along two parallel sides of the semiconductor chip 20. Alternatively, the board 40 for electrical connection may be disposed along four sides of the semiconductor chip 20. The board 40 for electrical connection may include an insulating section 42 and penetrating conductive sections 50. The board 40 for electrical connection, for example, may be formed by a step in which through holes are formed in the insulating section 42, and a step in which penetrating conductive sections 50 are formed in the through holes. The penetrating conductive sections 50 may be formed in a row within the board 40 for electrical connection. Alternatively, the penetrating conductive sections 50 may be formed in a plurality of rows and a plurality of columns within the board 40 for electrical connection. In this case, the penetrating conductive sections 50 may be disposed in a zigzag pattern. It should be noted that the material of the insulating section 42 is not particularly restricted, and for example glass epoxy resin may be used. The material of the penetrating conductive sections is not particularly restricted, and for example copper may be used.

The form of the penetrating conductive sections 50 is not particularly restricted, and for example as shown in FIGS. 4A and 4B, may be formed so that the cross-sectional area orthogonal to the lengthwise direction is greater close to the extremity. By means of this, since the surface area of the extremity can be increased, a semiconductor device of high electrical reliability can be manufactured. As shown in FIG. 4B, on the periphery of the second end surface 54 of the penetrating conductive sections 50, a depression 56 may be formed. The depression 56 may be formed to surround a central section 58 of the second end surface 54. In other words, the second end surface 54 may have the central section 58 surrounded by the depression 56. By means of this, even when in the resin sealing step described below, the molding resin enters over the second end surface 54, by means of the depression 56, the molding resin can be prevented from reaching the central section 58 of the second end surface 54. Therefore, the second end surface 54 (central section 58) can be reliably exposed, and a semiconductor device of high electrical reliability can be manufactured. It should be noted that FIG. 4B is an enlarged cross-section taken along the line IVB-IVB in FIG. 4A. However, the present invention is not limited to this, and the penetrating conductive sections 50 may be in the form of a prism (including a cylinder or polygonal prism), and the end surfaces may be flat.

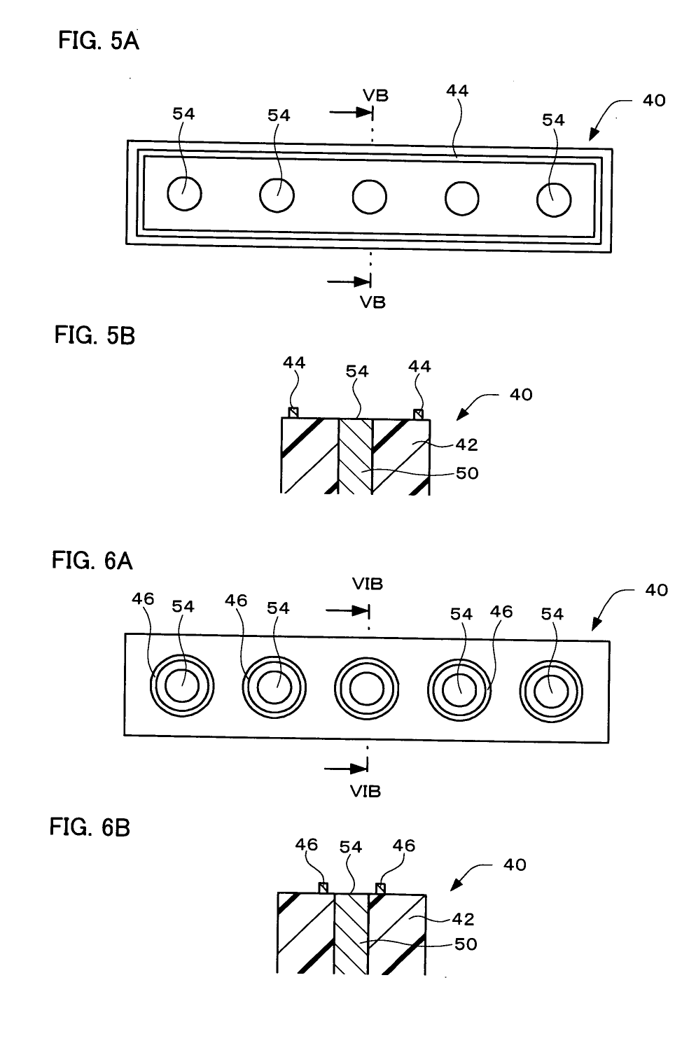

The form of the board 40 for electrical connection is not particularly restricted, and for example may be formed having a protrusion on the surface opposite to the surface opposing the wiring board 10. As shown in FIGS. 5A and 5B, on the periphery of the surface of the board 40 for electrical connection opposite to the surface opposing the wiring board 10 there may be a protrusion 44 formed so as to surround the second end surface 54 of all of the penetrating conductive sections 50. By means of this, in the resin sealing step, ingress of the molding resin over the second end surface 54 can be prevented by the protrusion 44. Therefore, the second end surface 54 can be exposed in a stable manner, and a semiconductor device of high electrical reliability can be manufactured. It should be noted that FIG. 5B is a partial enlarged cross-section taken along the line VB-VB in FIG. 5A. Alternatively, as shown in FIGS. 6A and 6B, the surface of the board 40 for electrical connection opposite to the surface opposing the wiring board 10 may have convexities 46 formed to surround the second end surface 54 of each of the penetrating conductive sections 50. Since a similar effect can be obtained by means of this, a semiconductor device of high electrical reliability can be manufactured. It should be noted that FIG. 6B is a partial enlarged cross-section taken along the line VIB-VIB in FIG. 6A. However, the form of the board 40 for electrical connection is not limited to these forms, and the board 40 for electrical connection may be formed as a rectangular parallelepiped (including a cube) not having any protrusion.

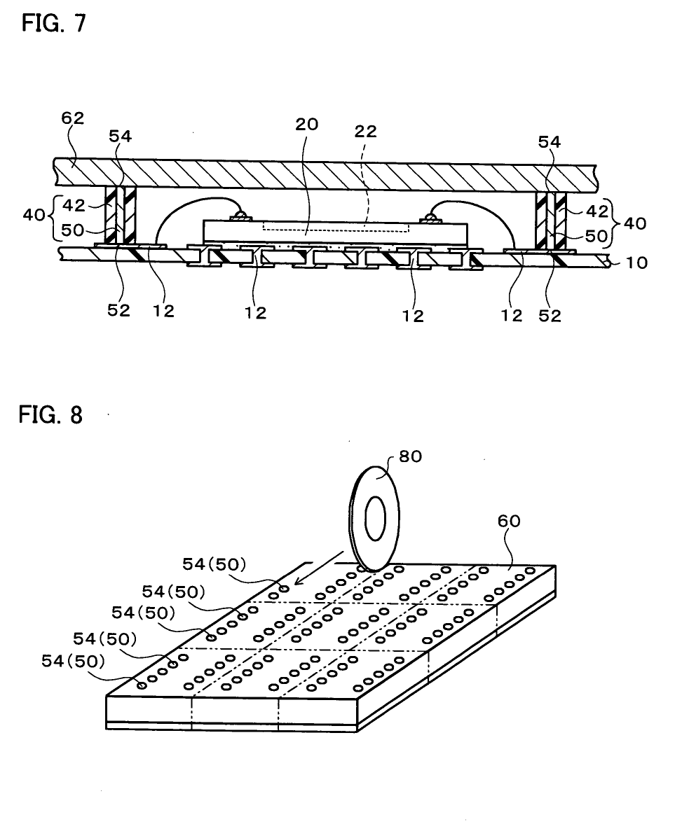

The method of manufacturing a semiconductor device according to this embodiment includes the formation of a sealing section 60 sealing the semiconductor chip 20 and board 40 for electrical connection. The sealing section 60 is formed by the transfer molding method. That is to say, as shown in FIG. 7, after the wiring board 10 on which the semiconductor chip 20 and board 40 for electrical connection are mounted is set on the die 62, a molding resin may be poured into the die 62 to form the sealing section 60. When a plurality of semiconductor chips 20 is mounted on a single wiring board 10, this plurality of semiconductor chips 20 may be sealed in a single operation (see FIG. 8). It should be noted that the material of the sealing section 60 is not particularly restricted, and the same material as the material of the insulating section 42 of the board 40 for electrical connection may be used, or a different material may be used.

In the method of manufacturing a semiconductor device according to this embodiment, the sealing section 60 is formed so that the second end surface 54 of the penetrating conductive sections 50 is exposed from the sealing section 60 (see FIG. 8). By causing the penetrating conductive sections 50 to be exposed, electrical connection to other semiconductor devices is made possible, and a stackable semiconductor device can be manufactured. If molding resin is injected into the die 62 with the molding die 62 pressed against the board 40 for electrical connection, then ingress of the molding resin over the second end surface 54 of the penetrating conductive sections 50 can be prevented, and the second end surface 54 can easily be exposed. It should be noted that when as described above the depression 56 is formed in the second end surface 54 of the penetrating conductive sections 50, or the protrusion 44 or convexities 46 are formed in the board 40 for electrical connection, ingress of the molding resin over the second end surface 54 of the penetrating conductive sections 50 can be effectively prevented, and therefore the second end surface 54 can be even more easily exposed.

Finally, as shown in FIG. 8, using a blade 80 or the like, the wiring board 10 and sealing section 60 may be cut into individual semiconductor chips 20, whereby a semiconductor device 1 is manufactured. The semiconductor device 1 has the wiring board 10 having the interconnecting pattern 12. The semiconductor device 1 has the semiconductor chip 20 in which the integrated circuit 22 is formed, mounted on the wiring board 10. The semiconductor device 1 has the board 40 for electrical connection having the insulating section 42 and plurality of penetrating conductive sections 50, mounted on the wiring board 10. The semiconductor device 1 has the sealing section 60 sealing the semiconductor chip 20 and board 40 for electrical connection. The first end surface 52 of the penetrating conductive section 50 opposes and is electrically connected to the interconnecting pattern 12. The second end surface 54 of the penetrating conductive sections 50 is exposed from the sealing section 60. The insulating section 42 and sealing section 60 may be formed of different materials. The semiconductor device 1 is formed so that a part of the penetrating conductive sections 50 (the second end surface 54) is exposed from the sealing section 60. Therefore, by means of the penetrating conductive sections 50, electrical conduction in the vertical direction among the semiconductor devices can be achieved. That is to say, a semiconductor device capable of being stacked in multiple layers can be provided. It should be noted that to other aspects of the construction of the semiconductor device 1, the content described in the above described method of manufacturing a semiconductor device can be applied.

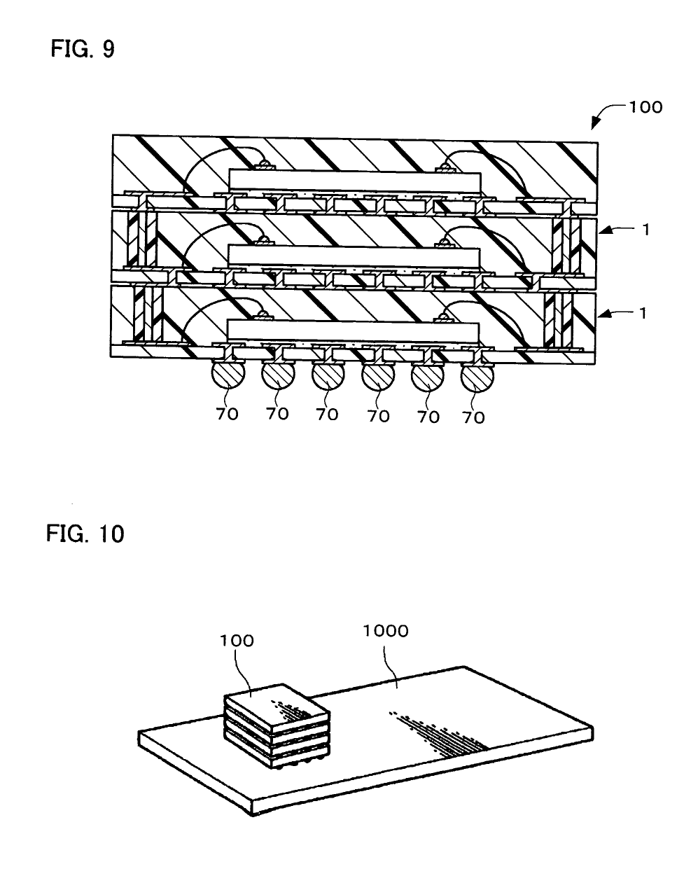

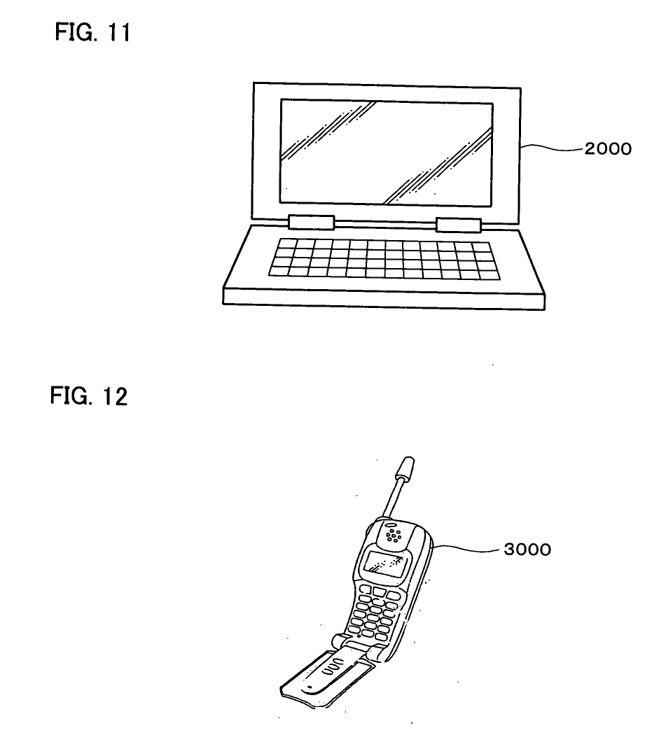

It should be noted that the semiconductor device 1 may be stacked, and external terminals 70 formed, to manufacture a stacked type of semiconductor device 100. In this case, as shown in FIG. 9, the penetrating conductive sections 50 may be contacted together, and the semiconductor devices 1 electrically connected in the vertical direction. In this case, the semiconductor devices 1 may be fixed together by an adhesive (not shown in the drawings). Alternatively, using ACF or ACP, conductive particles may be introduced between the penetrating conductive sections 50, and the semiconductor devices 1 may be electrically connected in the vertical direction with these interposed. FIG. 10 shows a circuit board 1000 on which is mounted the semiconductor device 100, and as electronic instruments having this semiconductor device 1, FIG. 1 shows a notebook personal computer 2000, and FIG. 12 shows a mobile telephone.

The present invention is not limited to the above-described embodiment, and various modifications can be made. For example, the present invention includes various other configurations substantially the same as the configurations described in the embodiment (in function, method and effect, or in objective and effect, for example). The present invention also includes a configuration in which an unsubstantial portion in the described embodiment is replaced. The present invention also includes a configuration having the same effects as the configurations described in the embodiment, or a configuration able to achieve the same objective. Further, the present invention includes a configuration in which a publicly known technique is added to the configurations in the embodiment.

1. A method of manufacturing a semiconductor device comprising:
mounting a semiconductor chip in which an integrated circuit is formed on a wiring board having an interconnecting pattern;
mounting a board for electrical connection having a plurality of penetrating conductive sections on the wiring board, disposing a first end surface of each of the penetrating conductive sections to face the interconnecting pattern and electrically connecting the first end surface and the interconnecting pattern; and
forming a sealing section which seals the semiconductor chip and the board for electrical connection such that a second end surface of each of the penetrating conductive sections is exposed from the sealing section by a transfer molding method.

2. The method of manufacturing a semiconductor device as defined in claim 1,
wherein a depression is formed in the periphery of the second end surface of each of the penetrating conductive sections.

3. The method of manufacturing a semiconductor device as defined in claim 1,
wherein a plurality of protrusions are formed to surround all of the second end surfaces of the penetrating conductive sections on the edge of a surface of the board for electrical connection opposite to the surface facing the wiring board.

4. The method of manufacturing a semiconductor device as defined in claim 2,
wherein a plurality of protrusions are formed to surround all of the second end surfaces of the penetrating conductive sections on the edge of a surface of the board for electrical connection opposite to the surface facing the wiring board.

5. The method of manufacturing a semiconductor device of claim 1,
wherein a protrusion is formed to surround the second end surface of each of the penetrating conductive sections on a surface of the board for electrical connection opposite to the surface facing the wiring board.

6. The method of manufacturing a semiconductor device of claim 2,
wherein a protrusion is formed to surround the second end surface of each of the penetrating conductive sections on a surface of the board for electrical connection opposite to the surface facing the wiring board.

7. A semiconductor device manufactured by the method as defined in claim 1.

8. A semiconductor device comprising:
a wiring board having an interconnecting pattern;
a semiconductor chip mounted on the wiring board and having an integrated circuit;
a board for electrical connection mounted on the wiring board and having an insulating section and a plurality of penetrating conductive sections; and
a sealing section which seals the semiconductor chip and the board for electrical connection;
wherein a first end surface of each of the penetrating conductive sections faces the interconnecting pattern and is electrically connected to the interconnecting pattern;
wherein a second end surface of each of the penetrating conductive sections is exposed from the sealing section; and
wherein the insulating section and the sealing section are formed of different materials.

9. A circuit board on which is mounted the semiconductor device as defined in claim 8.

10. An electronic instrument comprising the semiconductor device as defined in claim 8.
